(19) United States
(12) Patent Application Publication
(10) Pub. No.: US 2001/0018273 A1
(43) Pub. Date: Aug. 30, 2001

(54) Method of fabricating copper interconnecting line

(75) Inventors: Ji-Soon Park, Suwon-shi (KR); Soo-Geun Lee, Hwasong-gun (KR); Sun-Hoo Park, Yongin-shi (KR)

Correspondence Address: The Law Offices of Eugene M. Lee, PLLC, Suite 1200, 2111 Wilson Boulevard, Arlington, VA, 22201, US

(73) Assignee: Samsung Electronics Co., Ltd.

(21) Appl. No.: 09/745,866

(22) Filed: Dec. 26, 2000

(30) Foreign Application Priority Data
Dec. 23, 1999 (KR) 99-60871

(51) Int. Cl. H01L 21/31

(52) U.S. Cl. 438/762; 257/1

(57) ABSTRACT

A method of fabricating a semiconductor device employing a multi-layer metal interconnect structure that has a copper (Cu) interconnection layer. Low-temperature plasma processing is first performed on the surface of the Cu interconnection layer, an insulation layer is deposited on the plasma-processed Cu interconnection layer, and the resultant structure is thermally treated.

This application claims priority to an application entitled “Method of Fabricating Copper Interconnection Line” filed in the Korean Industrial Property Office on Dec. 23, 1999 and assigned Ser. No. 99-60871, the contents of which are hereby incorporated by reference.

### BACKGROUND OF THE INVENTION

1. Field of the Invention

The present invention relates generally to a method of fabricating a semiconductor device, and in particular, to a method of fabricating a semiconductor device using a copper interconnection line as a multi-layer metal interconnect structure.

2. Description of the Related Art

As semiconductor devices have become highly integrated, operation speed has dropped because of an increase in the resistance of metal interconnection lines for interconnecting specific devices and the parasite resistance between interconnection lines. The reduced operation speed has emerged as a significant issue. Especially in a semiconductor device having a transistor design rule of 0.25 μm or below, RC delay is more serious than the slow operation speed. As a result, even a decrease in the gate length of the transistor cannot contribute to an increase of the operation speed. Hence, an interconnection line has recently been formed of copper (Cu) whose interconnection resistance is about ⅓ of that of aluminum (Al), while a conventional metal interconnection line is typically formed by sputtering Al.

Meanwhile, with the advent of multi-layer interconnect structures in the field of semiconductor devices, many problems arise from an increased aspect ratio of a contact hole, such as non-planarization, bad step coverage, short circuits caused by metal remainders, low product yield, and reliability degradation. As a new interconnect technology to overcome the problems, a trench is formed by etching an insulation layer, a metal layer is deposited, filling the trench entirely, and an excess of the metal layer on the insulation layer is removed by CMP (Chemical Mechanical Polishing), so that a metal interconnection line is formed in the trench. This is called a damascene process. In the damascene process, the metal interconnection line is formed in intaglio in the trench of the insulation layer, usually in a line and space (L/S) pattern. A dual damascene process is widely used at present, in which filling a via hole or a contact hole is implemented simultaneously with formation of a metal interconnection line.

FIGS. 1, 2, and 3 are sectional views sequentially illustrating a conventional multi-layer metal interconnect forming method using a copper interconnection line and a dual damascene process.

Referring to FIG. 1, a first interconnection layer 10 is formed by depositing a metal, for example Al, Cu, or an Al alloy, on a semiconductor substrate (not shown) having an insulation layer formed thereon and patterning the metal by photolithography.

A first intermetal dielectric layer (IMD) 12 is formed by depositing an oxide film on the resultant structure having the first interconnection layer 10 formed thereon. A trench 14 is formed by etching the first IMD 12 to a predetermined depth by photolithography. Then, a first via hole 16 is formed to expose the surface of the first interconnection layer 10 by etching the first IMD 12 having the trench 14 formed thereinto by photolithography.

After a first Cu layer 18 is deposited on the resultant structure by sputtering or PVD (Physical Vapor Deposition), the trench 14 and the first via hole 16 are fully filled with Cu atoms moved from the first Cu layer 18 by electroplating (EP). Subsequently, the first Cu layer 18 is removed by CMP until the surface of the first IMD 12 is reached. Consequently, a first via plug is formed out of the first Cu layer 18 in the first via hole 16 and a second interconnection layer is formed out of the first Cu layer 18 in the trench 14. Generally, Cu is susceptible to surface oxidation and exhibits a low adhesion to an insulation layer. Therefore, an oxide film 20 is formed to a thickness of several tens of Å on the surface of the first Cu layer 18 after the CMP.

Referring to FIG. 2, a nitride layer 22 is deposited on the resultant structure including the first via plug and the second interconnection layer by plasma enhanced CVD (PECVD). The nitride layer 22 acts as a barrier layer in a subsequent CMP step and prevents the out-diffusion of Cu from the Cu layer 18. Then, a second IMD 24 is formed by depositing an oxide film on the nitride layer 22.

Referring to FIG. 3, a second via hole 26 is formed to expose the surface of the second interconnection layer formed of the first Cu layer 18 by etching the second IMD 24 by photolithography. After a second Cu layer 28 is deposited on the resultant structure, the second Cu layer 28 is removed from the barrier layer 22 by CMP, to thereby form a second via plug out of the second Cu layer 28 in the second via hole 26.

In the above conventional method, since the several tens of Å-thick oxide film has already been formed on the first Cu layer when the nitride layer is deposited on the first Cu layer, the adhesion between the nitride layer and the first Cu layer is bad. Thus, the nitride layer is lifted in the bad adhesion area, that is, at the interface surface between the nitride layer and the first Cu layer (see FIG. 3).

### SUMMARY OF THE INVENTION

It is, therefore, a feature of the present invention to provide a method of fabricating a semiconductor device using a copper interconnection line as a multi-layer metal interconnect structure, in which adhesion between a Cu layer and an overlying insulation layer can be increased without degradation of the surface morphology of the Cu layer.

In accordance with one aspect of the present invention, there is provided a method of fabricating a semiconductor device employing a multi-layer metal interconnect structure that has a copper (Cu) interconnection layer. Low-temperature plasma processing is first performed on the surface of the Cu interconnection layer, an insulation layer is deposited on the plasma-processed Cu interconnection layer, and the resultant structure is thermally treated.

Preferably, the low-temperature plasma processing is performed using an oxygen-free gas, more preferably ammonia (NH₃), at or below about 300° C.

Preferably, the low-temperature plasma processing step and the insulation layer deposition step are performed in situ.

Preferably, the thermal treatment is performed in an atmosphere that has a low-oxygen gas of less than 5% oxygen, preferably oxygen free.

Preferably, the thermal treatment is performed at or above about 300° C.

According to another aspect of the present invention, there is also provided a semiconductor device fabricating method. In the method, a first insulation layer is deposited on a semiconductor substrate, a first structure including a trench is formed by etching the first insulation layer, a Cu interconnection layer is formed by depositing a Cu layer on the first structure and removing the Cu layer from the surface of the first insulation layer, low-temperature plasma processing is performed on the surface of the Cu interconnection layer at or below about 300° C., a second structure is formed by depositing a barrier layer on the plasma-processed Cu interconnection layer, the second structure is thermally treated, a second insulation layer is deposited on the barrier layer, and a via hole is formed to expose the surface of the Cu interconnection layer by etching the second insulation layer.

Semiconductor devices prepared according to the inventive methods are also provided.

### BRIEF DESCRIPTION OF THE DRAWINGS

The above and other features and advantages of the present invention will become more apparent from the following detailed description when taken in conjunction with the accompanying drawings in which:

FIGS. 1, 2, and 3 are sectional views sequentially illustrating a conventional multi-layer metal interconnection line forming method for a semiconductor device; and

FIGS. 4 to 11 are sectional views sequentially illustrating a multi-layer metal interconnection line forming method for a semiconductor device according to the present invention.

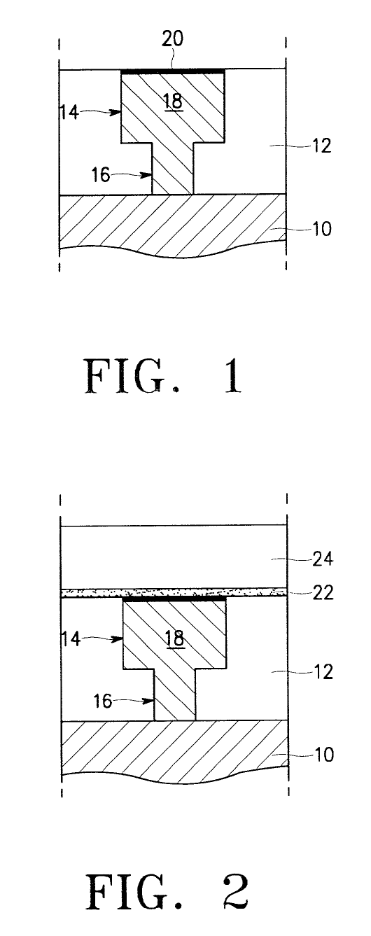

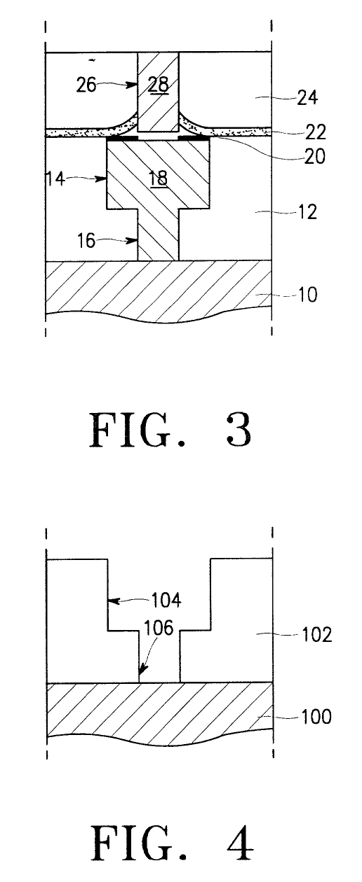

### DETAILED DESCRIPTION OF THE PREFERRED EMBODIMENTS

In the following description of preferred embodiments of the invention, a layer will be considered to be formed “on” an underlying layer if it is formed directly on the underlying layer or if it is formed on one or more intervening layers that are on the underlying layer.

A preferred embodiment of the present invention will be described hereinbelow with reference to the accompanying drawings. In the following description, well-known functions or constructions are not described in detail since they would obscure the invention in unnecessary detail.

FIGS. 4 to 11 are sectional views sequentially illustrating a multi-layer metal interconnection line forming method for a semiconductor device according to the present invention.

FIG. 4 illustrates the step of forming a trench 104 and first via hole 106. Conductive devices like transistors, bit lines, or capacitors formed on a semiconductor substrate are electrically isolated from a first interconnection layer by depositing an insulation layer (not shown) on the semiconductor substrate. An Al, Cu, or Al alloy is deposited on the insulation layer and then a capping layer (not shown) is formed of titanium (Ti) or Ti/TiN (Titanium Nitride) on the deposited metal layer. The capping layer and the metal layer are patterned by photolithography, thereby forming a first interconnection layer 100 as a wiring for the devices.

A first IMD 102 is formed by depositing an insulation layer, for example, an oxide film or a dielectric layer having a low dielectric constant to a thickness of about 5000 to 10,000 Å on the resultant structure having the first interconnection layer 100. A first photoresist pattern (not shown) is formed on the first IMD 102 by photolithography to define a trench area. A trench 104 is formed by etching the first IMD 102 to a depth of about 4000-5000 Å using the first photoresist pattern as a mask.

After the first photoresist pattern is stripped off, a second photoresist pattern (not shown) is formed on the first IMD 102 by photolithography to define a first via hole area. The first via hole 106 is formed to expose the surface of the first interconnection layer 100 by etching the first IMD 102 using the second photoresist pattern as a mask. Then, the second photoresist pattern is stripped off.

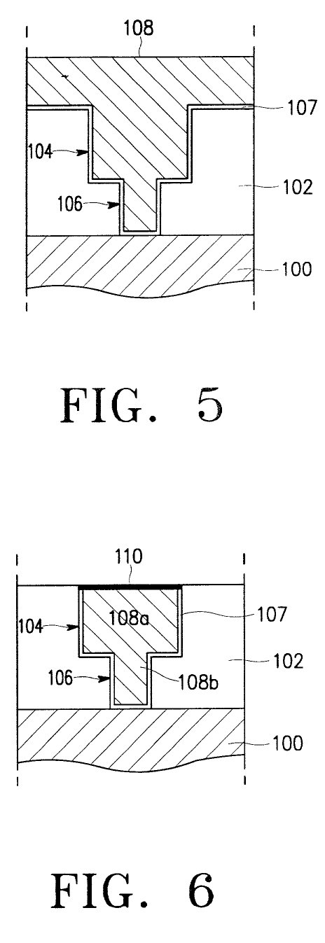

FIG. 5 illustrates the step of depositing a first metal barrier layer 107 and a first Cu layer 108. The first metal barrier layer 107 preferably is formed by depositing tantalum nitride (TaN), TiN, or tungsten nitride (WN) to a thickness of hundreds of angstroms, for example 100-900 angstroms, by sputtering on the resultant structure including the trench 104 and the first via hole 106.

Then, after the first Cu layer 108 is deposited on the first metal barrier layer 107 by sputtering or PVD, the trench 104 and the first via hole 106 are fully filled with the first Cu layer 108 by transferring Cu atoms from the first Cu layer 108 by EP.

FIG. 6 illustrates the step of forming a Cu interconnection layer 108a and a first Cu plug 108b. The first Cu layer 108 is removed from the surface of the first IMD 102 by CMP. As a result, the first Cu plug 108b is formed in the first via hole 106 and the Cu interconnection layer 108a is formed as a second interconnection line within the trench 104.

Due to the susceptibility to surface oxidation of Cu, an oxide film 110, having a thickness, for example, of about 5-50 Å, is formed on the surface of the CMP-completed Cu interconnection layer 108a.

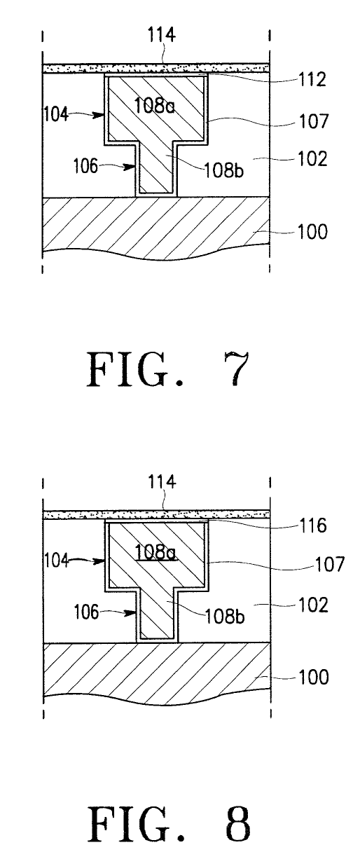

FIG. 7 illustrates the step of forming a barrier layer 114. The oxide film 110 on the Cu interconnection layer 108a is subjected to low-temperature plasma processing, and more specifically is nitrified by plasma processing, preferably NH₃ plasma processing, at or below about 300° C. Subsequently, the barrier layer 114 is formed by depositing a nitride layer to a thickness of about 700 Å on the Cu interconnection layer 108a, preferably by PECVD (Plasma Enhanced ChemicalVapor Deposition). The barrier layer 114 prevents the out-diffusion of Cu from the interconnection layer and serves as a polish stopping layer in a subsequent CMP step as well.

In a more specific preferred embodiment, the NH3 plasma processing is implemented at 200° C. and 2 Torr with 50-500 W of RF and more particularly 200 W of RF power. Also preferably, the flow rates of N₂ and NH₃ gases are 1500 and 80 sccm, respectively, and the distance between a wafer and a shower head for gas flow is 400 mil.

To prevent the surface of the Cu interconnection layer 108a from reoxidation during movement of the wafer, it is preferable to perform the plasma processing, preferably the NH₃ plasma processing, and the deposition of the barrier layer 114 in situ. For example, if a PECVD-nitride deposition apparatus includes multiple chambers, a wafer is moved from one chamber where the NH₃ plasma processing was performed to another chamber for nitride deposition.

According to the present invention, since the plasma processing (for example, NH₃ plasma processing) is done at or below about 300° C., neither Cu migration nor oxidation of the Cu layer occurs during the plasma processing. Therefore, even if the plasma processing is done for a long time, the surface morphology of the Cu interconnection layer 108a is not bad.

In FIG. 7, reference numeral 112 denotes the surface of the NH₃ plasma processed CU interconnection layer.

FIG. 8 illustrates a heat treatment step. After the barrier layer 114 is deposited, the barrier layer 114 is thermally treated at or above about 300° C., preferably about 400° C. To prevent the Cu interconnection layer 108a from being reoxidized through the barrier layer during the heat treatment, the heat treatment preferably is performed in a low-oxygen gas atmosphere, preferably in an N₂ atmosphere.

According to the present invention, the oxide film on the surface of the Cu interconnection layer 108a is nitrified without deteriorating the surface morphology of the Cu interconnection layer 108a by low-temperature NH₃ plasma processing before deposition of the barrier layer 114, and interface reaction is induced between the Cu interconnection layer 108a and the barrier layer 114 by performing the heat treatment after deposition of the barrier layer 114. As a result, the adhesion between the Cu interconnection layer 108a and the barrier layer 114 is increased.

In FIG. 8, reference numeral 116 denotes the heat-treated surface of the Cu interconnection layer.

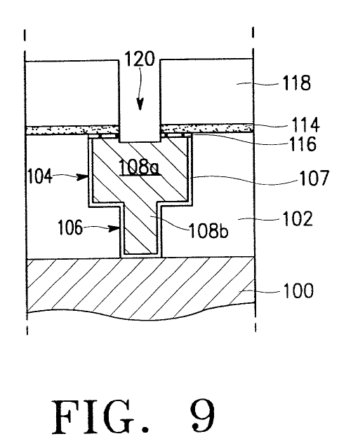

FIG. 9 illustrates the step of forming a second IMD 118 and a second via hole 120. After the heat treatment is completed, the second IMD 118 is formed by depositing an insulation layer, for example, TEOS to a thickness of about 5000 to 10,000 Å on the barrier layer 114, preferably by PECVD. Then, a third photoresist pattern (not shown) is formed on the second IMD 118 by photolithography to define a second via hole area. The second via hole 120 is formed to expose the surface of the Cu interconnection layer 108a by etching the second IMD 118 using the third photoresist pattern as a mask.

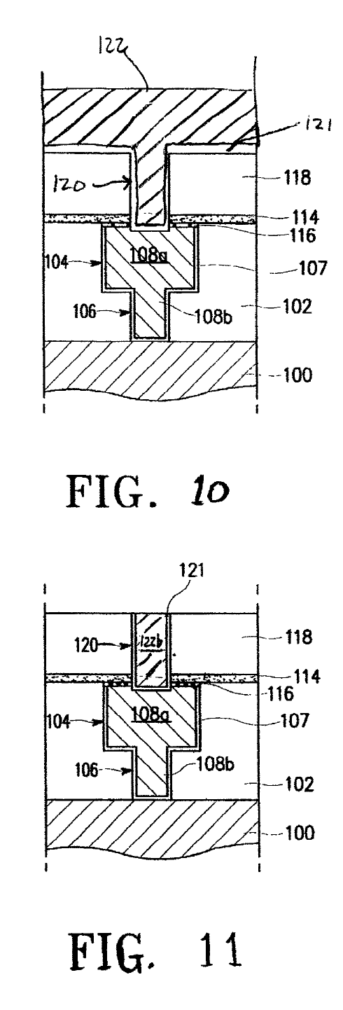

FIGS. 10 and 11 illustrate the step of forming a second Cu plug 122b. After the third photoresist pattern is stripped off, a second metal barrier layer 121 is formed by depositing TaN, TiN, or WN to a thickness of hundreds of angstroms by sputtering on the resultant structure. After a second Cu layer 122 is deposited on the second metal barrier layer 121 by sputtering or PVD, the second via hole 120 is fully filled with the second Cu layer 122 by transferring Cu atoms from the second Cu layer 122 by EP.

Then, the second Cu plug 122b is formed in the second via hole 120 by removing the second Cu layer 122 and the portions of barrier layer 121 on the surface of second IMD 118 by CMP.

While the second Cu plug is formed in a single-damascene method after the first Cu plug and the Cu interconnection layer are formed in a dual-damascene method in the above embodiment of the present invention, it can be contemplated that the first Cu plug and the Cu interconnection layer are formed in the single-damascene method. In addition, the present invention is applicable to the case that the Cu interconnection layer is used as the first wiring line.

In accordance with the present invention as described above, NH₃ plasma processing is performed at or below about 300° C. before deposition of the insulation layer and after formation of the Cu interconnection layer, so that the oxide film grown on the Cu interconnection layer is nitrified without deteriorating the surface morphology of the Cu interconnection layer. Then, a heat treatment is performed after the deposition of the insulation layer. Therefore, the adhesion between the Cu interconnection layer and the insulation layer is increased.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A method of fabricating a semiconductor device employing a multi-layer metal interconnect structure that has a copper (Cu) interconnection layer, comprising the steps of:
performing low-temperature plasma processing on the surface of the Cu interconnection layer;
forming a structure by depositing an insulation layer on the plasma-processed Cu interconnection layer; and
thermally treating the structure.

2. The method of claim 1, wherein the low-temperature plasma processing is performed using an oxygen-free gas at or below about 300° C.

3. The method of claim 2, wherein the low-temperature plasma processing is ammonia (NH₃) plasma processing.

4. The method of claim 1, wherein the low-temperature plasma processing step and the insulation layer deposition step are performed in situ.

5. The method of claim 1, wherein the thermal treatment is performed in a low-oxygen gas atmosphere.

6. The method of claim 1, wherein the thermal treatment is performed at or above about 300° C.

7. The method of claim 1, wherein the barrier layer is formed of a PECVD-nitride layer.

8. A semiconductor device fabricating method comprising the steps of:
depositing a first insulation layer on a semiconductor substrate;
forming a first structure including a trench by etching the first insulation layer;
forming a Cu interconnection layer by depositing a Cu layer on the first structure and removing the Cu layer from the surface of the first insulation layer;
performing low-temperature plasma processing on the surface of the Cu interconnection layer at or below about 300° C.;
forming a second structure by depositing a barrier layer on the plasma-processed Cu interconnection layer;
thermally treating the second structure;
depositing a second insulation layer on the barrier layer; and
forming a via hole exposing the surface of the Cu interconnection layer by etching the second insulation layer.

9. The method of claim 8, wherein the low-temperature plasma processing is performed using an oxygen-free gas.

10. The method of claim 9, wherein the low-temperature plasma processing is NH₃ plasma processing.

11. The method of claim 8, wherein the low-temperature plasma processing step and the barrier layer deposition step are performed in situ.

12. The method of claim 8, wherein the barrier layer is formed of a PECVD-nitride layer.

13. The method of claim 8, wherein the thermal treatment is performed in a low-oxygen gas atmosphere.

14. The method of claim 8, wherein the thermal treatment is performed at or above about 300° C.

15. A semiconductor device prepared according to the method of claim 1.

16. A semiconductor device prepared according to the method of claim 8.
